(19) United States
(12) Patent Application Publication
(10) Pub. No.: US 2024/0055498 A1
(43) Pub. Date: Feb. 15, 2024

(54) SEMICONDUCTOR DEVICE AND METHOD FOR PRODUCING SAME

(71) Applicant: mqSemi AG, Zug (CH)

(72) Inventors: Munaf RAHIMO, Gaensbrunnen (CH); Iulian NISTOR, Niederweningen (CH)

(21) Appl. No.: 17/766,500

(22) PCT Filed: Oct. 2, 2020
(86) PCT No.: PCT/EP2020/077744

§ 371 Date: Apr. 4, 2022

(30) Foreign Application Priority Data
Oct. 3, 2019 (GB) 1914275.1

(51) Int. Cl. H01L 29/423; H01L 29/06; H01L 29/739; H01L 29/10; H01L 29/78

(52) U.S. Cl. CPC H01L 29/4236; H01L 29/42376; H01L 29/42368; H01L 29/0696; H01L 29/7397; H01L 29/1095; H01L 29/7813; H01L 29/66348

(57) ABSTRACT

A Metal Oxide Semiconductor (MOS) trench cell concept adopts on a first surface of a semiconductor body a plurality of main gates extending lengthwise parallel to one another, and forming MOS channels, with transistor cell regions formed in a mesa of the semiconductor body between neighbouring main gates, and a drift layer in the semiconductor body s. The power semiconductor includes a plurality of second gates interwoven with the main gates at an angle of 45 degrees to 90 degrees to the longitudinal direction of the main gates. An additional gate structure can also be added to interconnect the second gates, leading to additional design flexibility by enabling forming additional MOS channels in the power semiconductor.

The new design can be applied to both IGBTs and MOSFETs based on silicon or wide bandgap materials such as Silicon Carbide SiC or Gallium Nitride GaN.

### RELATED APPLICATIONS

This application claims the benefit of PCT Application Serial No. PCT/EP2020/077744, filed Oct. 2, 2020, entitled “SEMICONDUCTOR DEVICE AND METHOD FOR PRODUCING SAME”, which claims the benefit of G.B. Application Serial No. 1914275.1, filed Oct. 3, 2019, entitled “SEMICONDUCTOR DEVICE AND METHOD FOR PRODUCING SAME”. The entirety of these applications are hereby incorporated by reference for all purposes.

### FIELD OF THE INVENTION

The invention relates to the field of power semiconductor devices. Power semiconductor devices that are able to withstand a blocking voltage of several hundred Volts at high current rating are typically implemented as vertical structures, wherein the semiconductor wafer is based for example on a semiconducting material such as silicon (Si) or silicon carbide (SiC) or diamond or gallium oxide (Ga2O3) or gallium nitride (GaN).

### BACKGROUND

Planar and Trench MOS cell designs exhibit a number of advantages and disadvantages for IGBT and MOSFET designs. For IGBTs, typical Planar and Trench designs are shown in FIGS. 1 and 2. Both designs can also incorporate an enhancement n-type layer for improved excess carrier storage (not shown in figures).

FIG. 1 shows a prior art IGBT with planar gate electrodes. The IGBT (200) is a device with a four-layer structure, which are arranged between an emitter electrode (3) on an emitter side (31) and a collector electrode (2) on a collector side (21), which is arranged opposite of the emitter side (31). An N-doped drift layer (4) is arranged between the emitter side (31) and the collector side (21). A P-doped planar base layer (9) is arranged between the drift layer (4) and the emitter electrode (3), which planar base layer (9) is in direct electrical contact to the emitter electrode (3). A planar N-doped source region (7) is arranged on the emitter side (31) embedded into the planar base layer (9), and contacting the opening (14) to the emitter electrode (3). In addition, a planar P-doped region (8) is arranged on the emitter side (31) below region (7) and embedded into the planar base layer (9), and a contact opening (14) through region (7) and extending to region (8) is formed for the emitter electrode (3).

A planar gate electrode (10) is arranged on top of the emitter side (31). The planar gate electrode (10) is electrically insulated from the planar base layer (9), the planar source region (7) and the drift layer (4) by a planar insulating layer (12). There is a further insulating layer (13) arranged between the planar gate electrode (10) and the emitter electrode (3).

The planar cell concept offers a lateral MOS channel (15) which suffers from non-optimal charge spreading (so called JFET effect) near the cell resulting in low carrier enhancement and higher conduction losses. Furthermore, due to the lateral channel design, the planar cell design suffers also from the PNP bipolar transistor hole drain effect (PNP effect) due to the bad spreading of electrons flowing out of the MOS channel. However, the accumulation layer between the MOS cells offers strong charge enhancement for the PIN diode part (PIN effect). The planar design also requires more area resulting in less cell packing density for reduced channel resistance.

On the other hand, the planar design provides good blocking capability due to low peak fields at the cell and in between. The planar design can also provide good controllability and low switching losses due to the presence of direct path to extract the bipolar charge stored between the MOS cells (50) near the emitter side (31). The cell densities in planar designs are also easily adjusted for the required short circuit currents. Due to the fact that there exist few high peak electric fields in the gate oxide regions, the planar design offers good reliability with respect to parameter shifting during operation under high voltages. Also, the introduction of enhanced layers in planar cells has resulted in lower losses rivalling those achieved with trench designs as explained below.

The trench cell concept for a trench IGBT 300 shown in FIG. 2 provides a trench gate electrode (11) which offers a vertical MOS channel (16) for achieving enhanced injection of electrons in the vertical direction and suffer from no drawbacks from charge spreading (JFET effect) near the cell. Therefore, the trench cells show much improved carrier enhancement for lower conduction losses.

Due to the vertical channel design, the trench also offers less hole drain effect (PNP effect) due to the improved electron spreading out of the MOS channel. Modern trench designs adopting mesa widths (trench to trench distance) below 1 μm achieve very low conduction losses since closely packed trenches can provide a strong barrier to hole drainage. Matching such a performance with less complex processes can be of a great advantage. The accumulation layer at the bottom of the trench offers strong charge enhancement for the PIN diode part. Hence wide and/or deep trenches show optimum performance. Furthermore, the trench design offers large cell packing density for reduced channel resistance.

However, the trench design suffers from lower blocking capability near the bottom corners of the trenches due to high peak electric fields. This has also resulted in parameter shifting during operation due to hot carrier injection into the trench gate oxide (12′). The trench design has also a large MOS accumulation region and associated capacitance resulting in bad controllability and high switching losses. The high cell densities in trench designs will also result in high short circuit currents. Finally, gate parameter shifts can occur under normal gate biasing stress conditions due to the trench etch process in relation to the silicon crystal orientation and the critical region at the n-source and p-base junction which is formed at the trench gate oxide (12′) and defines the device MOS parameters.

Hence, optimising the trench design to overcome the above drawbacks has normally resulted in higher losses when compared to the initial loss estimations and potential of trench designs. Many trench designs have been proposed with particular focus on the regions between the active MOS cells for lowering the losses and improving the device controllability.

By way of example, FIG. 3 shows a prior art “repetitive trench design” cross section along the cut line A-A′ indicated in the top view of such a design layout shown in FIG. 4. In many cases, in order to optimise the electrical characteristics (e.g., capacitances) of the device, dummy cells, as shown in FIG. 5, or grounded trenches (11′) with the gate electrode in direct electrical contact with the electrode (3), as shown in FIG. 6, or a combination of dummy cells and grounded trenches have been proposed as possible solutions in the prior art.

By way of example, FIG. 7 shows a prior art “non-repetitive trench design” cross section along the cut line A-A′ indicated in the top view of such a design layout shown in FIG. 8. Non-repetitive trench cell is a design with a pitch separating adjacent trench cells regions. Such a design provides good overall performance. However, in such trench cell designs, a direct path for charge extraction (50) is not provided as in the planar cell designs. This results in non-optimum switching and requires some contact to be established to the pitch area between cells. This normally results in higher on-state losses. Hence, a trade-off between device controllability and losses is present in most modern trench cell designs.

In further prior art, an alternative approach was disclosed that proposed an arrangement of non-contacting orthogonal first and second gate trenches. This approach has multiple limitations, for example it is difficult to reduce the distance between adjacent gate trenches to submicron dimensions, because additional source regions and base layers must be formed between two adjacent gate trenches (both for first and second gate trenches). A highly doped base layer extends uniformly between the source regions, along the long edge of the second gate trenches. The emitter electrode is extended uniformly over the first main surface of the device, contacting the highly doped base layer, which can lead for example to safe operating area issues or increased hole drainage effect.

### SUMMARY

It is desirable to find a new MOS cell design concept that can still benefit from the trench cell concept while enabling simple process steps and lower conduction/on-state losses.

It may be an object of the present invention to provide a power semiconductor device with reduced on-state losses, low drainage of holes, stable gate parameters, improved blocking capability, and good controllability such as an Insulated Gate Bipolar Transistor (IGBT) with improved electrical characteristics.

According to a first aspect of the invention we herein describe a power semiconductor device comprising: a drift region of a first conductivity type comprising a first surface and a second surface separated in a first dimension, wherein the first surface and second surface are parallel surfaces; a first electrode located at the first surface; a second electrode located at the second surface; a first base layer of a second conductivity type located between the first electrode and the drift region; a source region of the first conductivity type located within the first base layer and electrically connected to the first electrode via a contact opening, wherein a doping concentration of the source region is greater than a doping concentration of the drift region; a second base layer of the first conductivity type located within the first base layer and electrically connected to the first electrode via the contact opening, wherein a length of the second base layer in the first dimension is greater than a length of the source region in the first dimension, and wherein a doping concentration of the second base layer is greater than a doping concentration of the first base layer; a plurality of first gate electrodes of a heavily doped polycrystalline layer or a metal layer and located within the first base layer and the drift region, wherein: the first gate electrode is electrically insulated from the first base layer, the source region, and the drift layer by a first gate oxide layer; the first gate electrode is configured to form an MOS channel in the first dimension between the first electrode and the drift region; and wherein the first gate electrode extends in a second dimension perpendicular to the first dimension; a plurality of second gate electrodes of a heavily doped polycrystalline layer or a metal layer and located within the first base layer and the drift region, wherein: the second gate electrodes are electrically insulated from the first base layer, the source region, and the drift layer by a second gate oxide layer; the second gate electrodes extend in a third dimension perpendicular to the first dimension, wherein the third dimension is oriented at an angle of greater than or equal to 45 degrees from the second dimension; and the second gate electrodes are separated from the first gate electrode in the third dimension; an interlayer dielectric layer formed between the first electrode and the first gate electrode and formed between the first electrode and the second gate electrodes; and wherein the contact opening is arranged between the first gate electrode and the second gate electrodes.

It will be understood that the first dimension generally relates to the direction of the separation of the first (emitter) and second (collector) electrodes. Similarly, the second dimension relates to the longitudinal direction or length of the first (main) gate electrode, and the third dimension relates to the longitudinal direction or length of the second gate electrodes. Generally, both the second and third dimensions are perpendicular to the first dimension. Additionally, the third dimension may be at an angle of between 45 degrees and 90 degrees to the second dimension.

A separation between adjacent second gate electrodes in the second dimension may be between 5 μm to 0.1 μm. For example, the separation between adjacent second gate electrodes in the second dimension is less than 1 μm. A separation between the first gate electrode and the second gate electrodes in the third dimension may be between 20 μm and 0.5 μm. For example, the separation may be less than 5 μm or less than 2 μm.

In a further embodiment the first gate electrodes may each be located in a respective first trench structure and/or the second gate electrodes may each be located in respective parallel second trench structures. At least two of the second trench structures may be separated in the third dimension by the first trench structure. In other words, at least two of the second trench structures may be formed on opposite sides of the first trench structure.

In a further embodiment, at least two of the second trench structures have an equal length in the third dimension.

In a further embodiment, at least two adjacent second trench structures have different lengths in the third dimension.

In a further embodiment, at least two of the second trench structures have different separations to the first gate electrode in the third dimension.

In a further embodiment, at least two of the second trench structures have an equal depth in the first dimension.

In a further embodiment, at least two adjacent second trench structures have different depths in the first dimension.

In a further embodiment, at least one of the second trench structures has a greater depth in the first dimension than the first trench structure.

In a further embodiment, at least two of the second trench structures have an equal width in the second dimension.

In a further embodiment, at least two adjacent second trench structures have different widths in the second dimension.

In a further embodiment, at least one of the second trench structures has a greater width in the second dimension than a width of the first trench structure in the third dimension.

In some embodiments, the second gate oxide layer may be identical to the first gate oxide layer. Alternatively, the first and second oxide layers may be different. For example, they may have a different thickness and/or chemical composition.

In some embodiments, a MOS channel is formable in the first dimension around the second gate electrodes. Alternatively, the first and second gate electrodes may be electrically connected, and no MOS channel is formable in the first dimension on the surface of the second gate electrodes.

In a further embodiment, all or some of the second gate electrodes may be electrically connected to the first electrodes. Additionally, or alternatively, all or some of the second gate electrodes may be electrically floating.

In another embodiment, some or all of the second gate electrodes may be interconnected on the first side via a third gate electrode located above the first surface. Optionally, the third gate electrode may be located above the drift region and not be in a trench structure. The device may further comprise an insulating layer located beneath the third electrode, wherein at least part of the third electrode is separated from the drift region by only the insulating layer. By forming the third electrode above an N-source region, a planar or horizontal MOS channel may be formed.

The power semiconductor device may further comprise at least one of: a collector layer of the second conductivity type formed between the drift region and the second electrode; and a buffer layer of the first conductivity type formed between the drift region and the second electrode, wherein a doping concentration of the buffer layer is greater than a doping concentration of the drift region. Optionally, if the device comprises both the buffer layer and the collector layer, the buffer layer may be formed between the collector layer and the second electrode.

In some embodiments, the device may further comprise a reverse conducting type device with a shorted collector layer arranged at the second surface between the second electrode and the buffer layer, wherein the shorted collector layer is formed by a pattern of opposite conductivity type regions.

In a further embodiment, an enhancement layer of the first conductivity type may be located between the drift region and the first base layer.

The power semiconductor device may have a stripe layout design or a cellular layout design.

According to a second aspect of the invention, it is described a semiconductor module package comprising one or more power semiconductor devices comprising: a drift region of a first conductivity type comprising a first surface and a second surface separated in a first dimension, wherein the first surface and second surface are parallel surfaces; a first electrode located at the first surface; a second electrode located at the second surface; a first base layer of a second conductivity type located between the first electrode and the drift region; a source region of the first conductivity type located within the first base layer and electrically connected to the first electrode via a contact opening, wherein a doping concentration of the source region is greater than a doping concentration of the drift region; a second base layer of the first conductivity type located within the first base layer and electrically connected to the first electrode via the contact opening, wherein a length of the second base layer in the first dimension is greater than a length of the source region in the first dimension, and wherein a doping concentration of the second base layer is greater than a doping concentration of the first base layer; at least one first gate electrode of a heavily doped polycrystalline layer or a metal layer and located within the first base layer and the drift region, wherein: the first gate electrode is electrically insulated from the first base layer, the source region, and the drift layer by a first gate oxide layer; the first gate electrode is configured to form an MOS channel in the first dimension between the first electrode and the drift region; and wherein the first gate electrode extends in a second dimension perpendicular to the first dimension; a plurality of second gate electrodes of a heavily doped polycrystalline layer or a metal layer and located within the first base layer and the drift region, wherein: the second gate electrodes are electrically insulated from the first base layer, the source region, and the drift layer by a second gate oxide layer; the second gate electrodes extend in a third dimension perpendicular to the first dimension, wherein the third dimension is oriented at an angle of greater than or equal to 45 degrees from the second dimension; and the second gate electrodes are separated from the first gate electrode in the third dimension; an interlayer dielectric layer formed between the first electrode and the first gate electrode and formed between the first electrode and the second gate electrodes; and wherein the contact opening is located between the first gate electrode and the second gate electrodes.

According to a third aspect of the invention, it is described a converter with a plurality of power semiconductor devices comprising: a drift region of a first conductivity type comprising a first surface and a second surface separated in a first dimension, wherein the first surface and second surface are parallel surfaces; a first electrode located at the first surface; a second electrode located at the second surface; a first base layer of a second conductivity type located between the first electrode and the drift region; a source region of the first conductivity type located within the first base layer and electrically connected to the first electrode via a contact opening, wherein a doping concentration of the source region is greater than a doping concentration of the drift region; a second base layer of the first conductivity type located within the first base layer and electrically connected to the first electrode via the contact opening, wherein a length of the second base layer in the first dimension is greater than a length of the source region in the first dimension, and wherein a doping concentration of the second base layer is greater than a doping concentration of the first base layer; at least one first gate electrode of a heavily doped polycrystalline layer or a metal layer and located within the first base layer and the drift region, wherein: the first gate electrode is electrically insulated from the first base layer, the source region, and the drift layer by a first gate oxide layer; the first gate electrode is configured to form an MOS channel in the first dimension between the first electrode and the drift region; and wherein the first gate electrode extends in a second dimension perpendicular to the first dimension; a plurality of second gate electrodes of a heavily doped polycrystalline layer or a metal layer and located within the first base layer and the drift region, wherein: the second gate electrodes are electrically insulated from the first base layer, the source region, and the drift layer by a second gate oxide layer; the second gate electrodes extend in a third dimension perpendicular to the first dimension, wherein the third dimension is oriented at an angle of greater than or equal to 45 degrees from the second dimension; and the second gate electrodes are separated from the first gate electrode in the third dimension; an interlayer dielectric layer formed between the first electrode and the first gate electrode and formed between the first electrode and the second gate electrodes; and wherein the contact opening is located between the first gate electrode and the second gate electrodes.

### BRIEF DESCRIPTION OF THE DRAWINGS

The embodiments of the invention will be explained in more detail in the following text with reference to the attached drawings, in which:

FIG. 1: shows the cross section of a Planar MOS IGBT structure (prior art).

FIG. 2: shows the cross section of a Trench MOS IGBT structure (prior art).

FIG. 3: shows the cross section of a repetitive Trench MOS IGBT structure (prior art).

FIG. 4: shows a top view representation of the repetitive Trench MOS IGBT structure in FIG. 3 (prior art).

FIG. 5: show the top view of Trench MOS IGBT structure with dummy cells (prior art).

FIG. 6: show the top view of Trench MOS IGBT structure with grounded trenches (prior art).

FIG. 7: shows the cross section of a non-repetitive Trench MOS IGBT structure (prior art).

FIG. 8: shows a top view representation of the non-repetitive Trench MOS IGBT structure in FIG. 7 (prior art).

FIG. 9: shows a top view representation of a first exemplary embodiment of a Trench MOS IGBT structure according to the invention.

FIG. 10: shows the cross section along A-A′ of first exemplary embodiment according to the invention.

FIG. 11: shows the cross section along B-B′ of first exemplary embodiment according to the invention.

FIG. 12: shows a top view representation of a second exemplary embodiment of a Trench MOS IGBT structure according to the invention, where a layer of polysilicon or metal is used to connect the trenches.

FIG. 13: shows a top view representation of a third exemplary embodiment of a Trench MOS IGBT structure according to the invention, where a layer of polysilicon or metal is used to connect the trenches and form a lateral/horizontal MOS channel.

FIG. 14: shows the cross section along B-B′ of third exemplary embodiment according to the invention.

FIG. 15: shows a top view representation of a fourth exemplary embodiment of a Trench MOS IGBT structure according to the invention, where a layer of polysilicon or metal is used to connect the trenches.

FIG. 16: shows a top view representation of a fifth exemplary embodiment of a Trench MOS IGBT structure according to the invention, where a layer of polysilicon or metal is used to connect the trenches and form a lateral/horizontal MOS channel.

FIG. 17: shows a top view representation of a sixth exemplary embodiment with the first and second plurality of trench gate structures forming an angle different than 90 degrees.

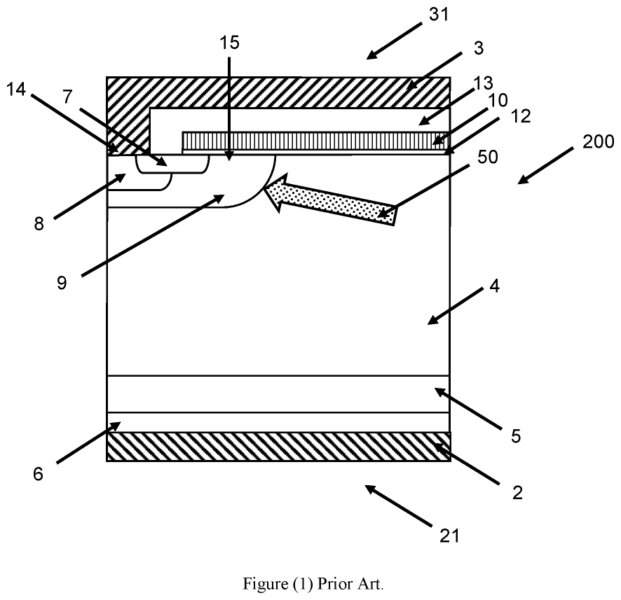

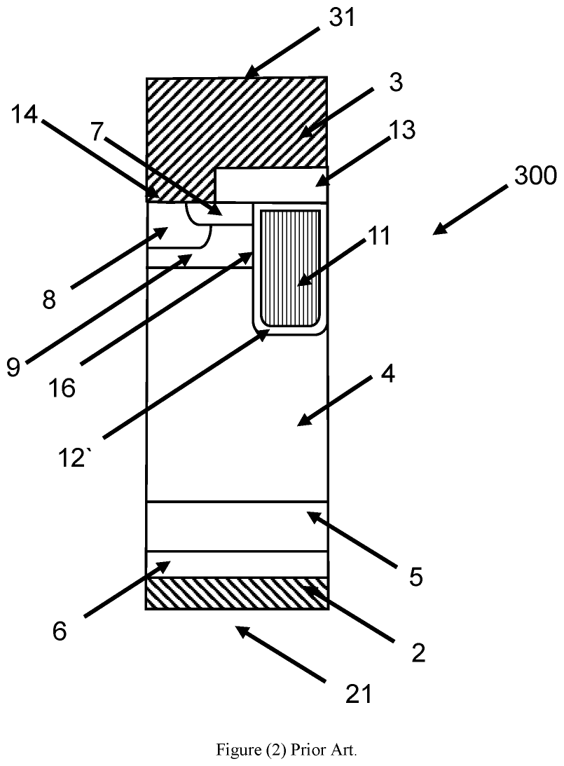

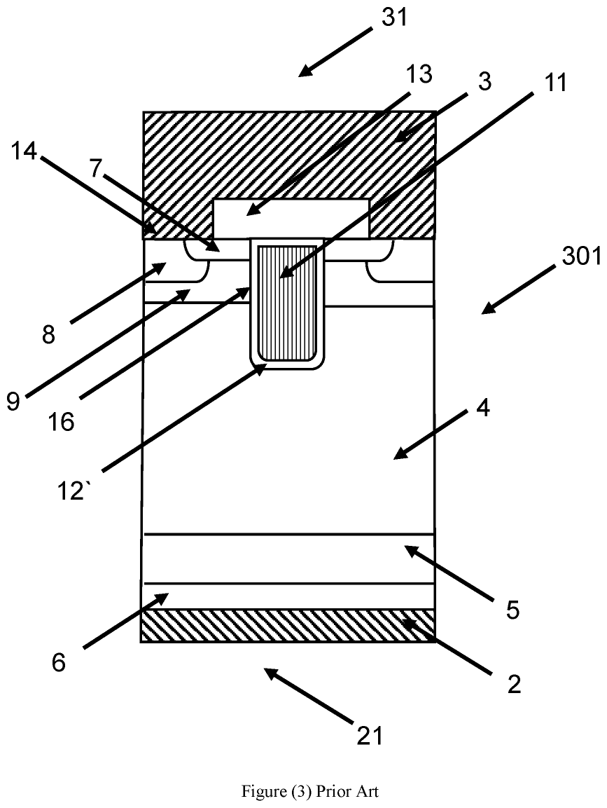

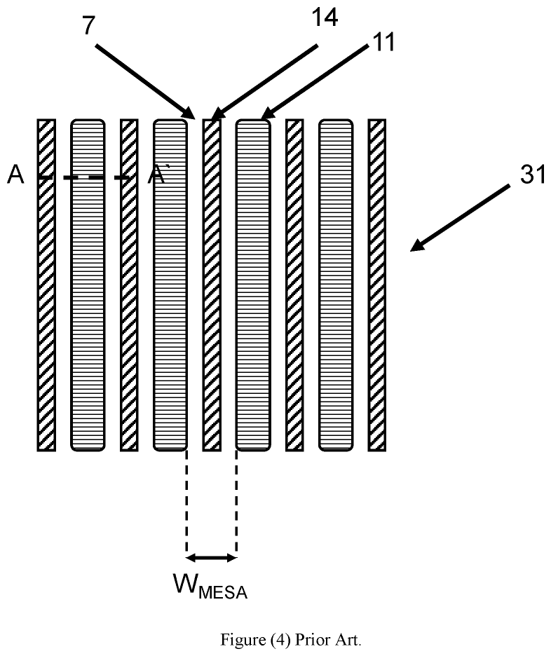

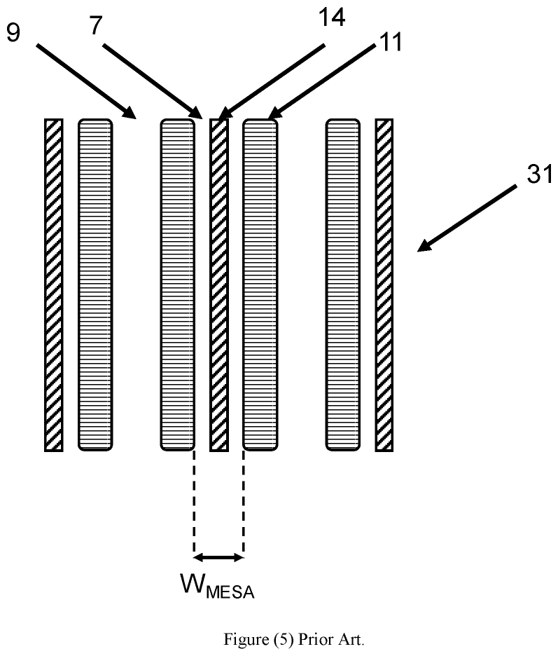

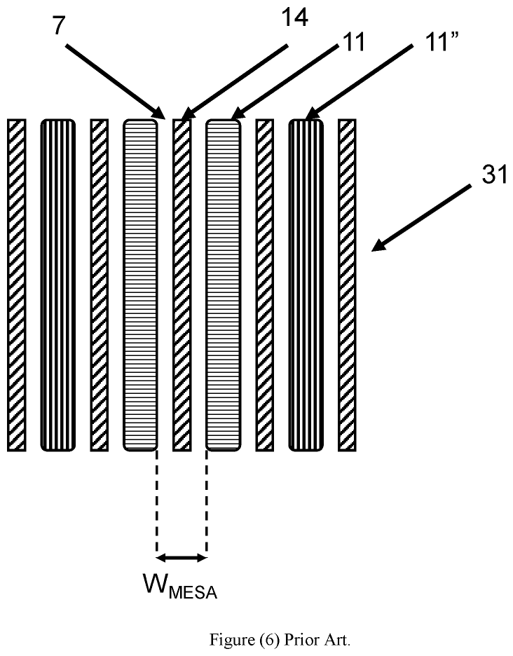

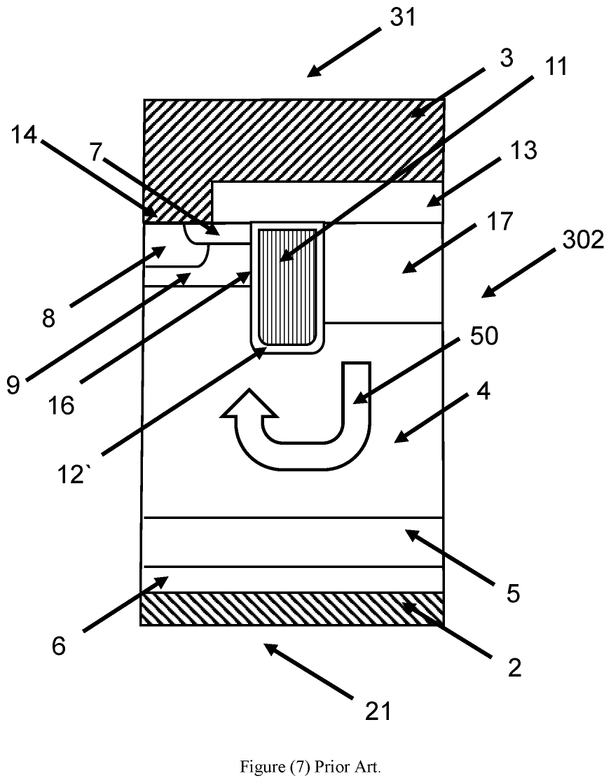

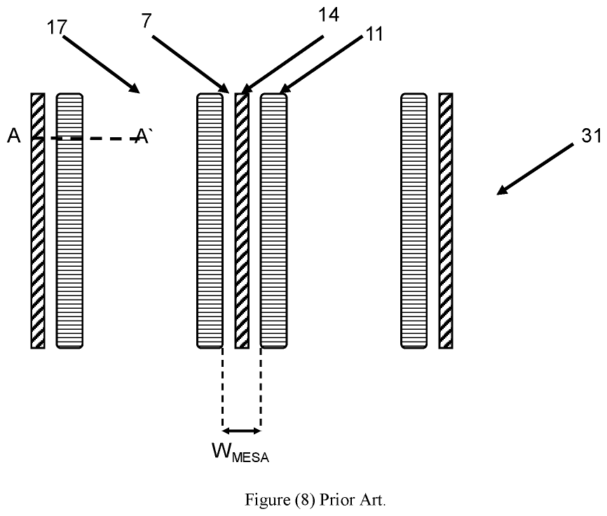

The reference symbols used in the figures and their meaning are summarized in the list of reference symbols. The drawings are only schematically and not to scale. Generally, alike or alike-functioning parts are given the same reference symbols. The described embodiments are meant as examples and shall not confine the invention.

### DETAILED DESCRIPTION

We herein describe a power semiconductor device having layers of different conductivity types, which layers are arranged between an emitter electrode on an emitter side and a collector electrode on a collector side, which is arranged opposite of the emitter side. The layers comprise:
a drift layer of a first conductivity type, which is arranged between the emitter side and the collector side,
an emitter electrode with multiple contact openings,
a first base layer of a second conductivity type, which is arranged between the drift layer and the emitter electrode,
a source region of the first conductivity type, which is arranged at the emitter side embedded into the first base layer and contacts the emitter electrode, which source region has a higher doping concentration than the drift layer, and extends to the first and second gate electrode,
a second base layer of the second conductivity type, which is arranged at the emitter side embedded into the first base layer and is situated deeper than the source region, and contacts the emitter electrode, which second base layer region has a higher doping concentration than the first base layer, and is in direct electrical contact to the emitter electrode,
a plurality of main trench gate structures arranged on top of the emitter side and extending in the drift layer deeper than the first base layer; characterized in that, the longitudinal direction of the main gate trenches is oriented along a first horizontal direction; and characterized in that, the first horizontal direction can be a specific crystallographic axis in the starting material, or can be randomly selected. The main gate electrodes are electrically insulated from the first base layer, the source region and the drift layer by a by a main gate oxide, a vertical channel is formable between the emitter electrode, the first source region, the first base layer and the drift layer,
plurality of second trench gate structures arranged on top of the emitter side and extending vertically in the drift layer, having possibly different geometrical dimensions than those of the main trench gate structures. The longitudinal direction of the second trench gate structures forms an angle of between 45 degrees to 90 degrees with reference to the first horizontal direction (being also the longitudinal direction of the main gate structures). All or only some of the second trench gate structures are discontinued in their longitudinal direction. The second gate electrodes are electrically insulated from the first base layer and the drift layer by a second gate oxide, which second gate oxide can be identical, or made from a different material, or with a different thickness specification than the first gate oxide.

When a positive voltage is applied on the main and second gate electrodes, a vertical channel can be formable between the emitter electrode, the first source region, the first base layer and the drift layer along the short and long edges of the first and second trench gates.

The second base layer is structured to not fully cover the long edge of the second gate trenches. Instead, the second base layer and the contact openings of the emitter electrode are formed so as to be encompassed roughly within the separation distance between the long edge of the main gate trench recess, and the short edge of its nearest second gate trench recesses. This ensures a particularly robust switching capability for the power semiconductor, while reducing the hole drainage effect.

The semiconductor device improves a Trench MOS cell in order to gain the advantages of both designs in terms of reduced on-state losses, low drainage of holes, stable gate parameters, improved blocking and good controllability.

Due to the fact that the area in between the second trench gate structures does not need to be further structured, very high-density trench patterns can be used, with trench mesa dimensions below 100 nm. This will significantly reduce the hole drainage effect as well known to those experts in the field.

In addition, for discontinued second gate trenches at the main trench cells, the trench mesa dimension can be reduced to 1 μm for further reducing the hole drainage effect while keeping the trench cell dimensions larger than 1 μm.

Some or all of the plurality of second gate electrodes can be directly connected to the main gate electrodes, or can be directly connected to the emitter electrode, or made floating. If the second gate electrodes are shorted to the emitter electrode, there is no voltage differential between the second gate electrodes and effectively no capacitance. Since the second gates do not invert the first base region, the cell containing the second gate is a passive type of cell, as opposed to an active cell controlled by the gate trenches. By controlling the number of passive cells, the input capacitance of the device can be precisely controlled.

Similarly, if the second gate electrodes are floating, resulting in a passive cell, the potential floats up to the emitter voltage so there is effectively no capacitance associated with the second gates.

The new design offers a wide range of advantages both in terms of performance (reduced losses, improved controllability and reliability), and processability (very narrow mesa design rules, reliable process compatibility) with the potential of applying enhanced layer structures. The inventive design is suitable for full or part stripes but can also be implemented in cellular designs.

The inventive design is also suitable for reverse conducting structure and can be applied to both IGBTs and MOSFETs based on silicon or wide bandgap materials such as Silicon Carbide (SiC).

Those skilled in the art will recognize additional features and advantages upon reading the following detailed description and on viewing the accompanying drawings.

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Reference will now be made in detail to various embodiments, one or more examples of which are illustrated in the figures. Each example is provided by way of explanation, and is not meant as a limitation of the invention. For example, features illustrated or described as part of one embodiment can be used on or in conjunction with other embodiments to yield yet a further embodiment. It is intended that the present invention includes such modifications and variations. The examples are described using specific language which should not be construed as limiting the scope of the appending claims. The drawings are not scaled and are for illustrative purposes only. For clarity, the same elements or manufacturing steps have been designated by the same references in the different drawings if not stated otherwise.

Unless otherwise defined, all terms (including technical and scientific terms) used herein have the same meaning as commonly understood by one of ordinary skill in the art to which example embodiments belong. It will be further understood that terms, e. g., those defined in commonly used dictionaries, should be interpreted as having a meaning that is consistent with their meaning in the context of the relevant art. However, should the present disclosure give a specific meaning to a term deviating from a meaning commonly understood by one of ordinary skill, this meaning is to be taken into account in the specific context this definition is given herein.

In this specification, N-doped is referred to as first conductivity type while P-doped is referred to as second conductivity type. Alternatively, the semiconductor devices can be formed with opposite doping relations so that the first conductivity type can be P-doped and the second conductivity type can be N-doped.

Specific embodiments described in this specification pertain to, without being limited thereto, insulated gate bipolar semiconductor devices.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e. g. “between” versus “directly between”, “adjacent” versus “directly adjacent,” etc.).

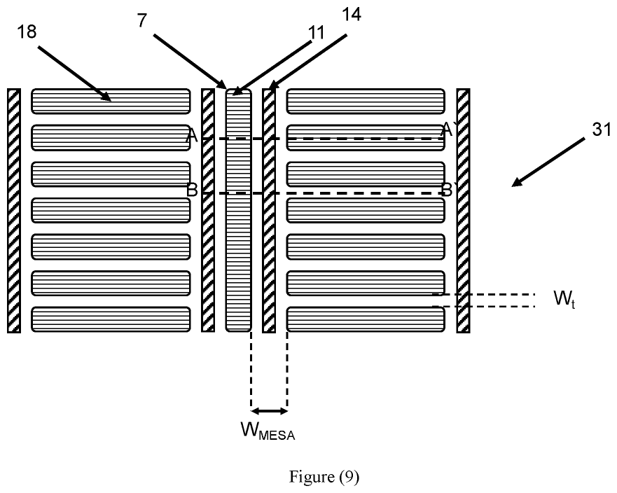

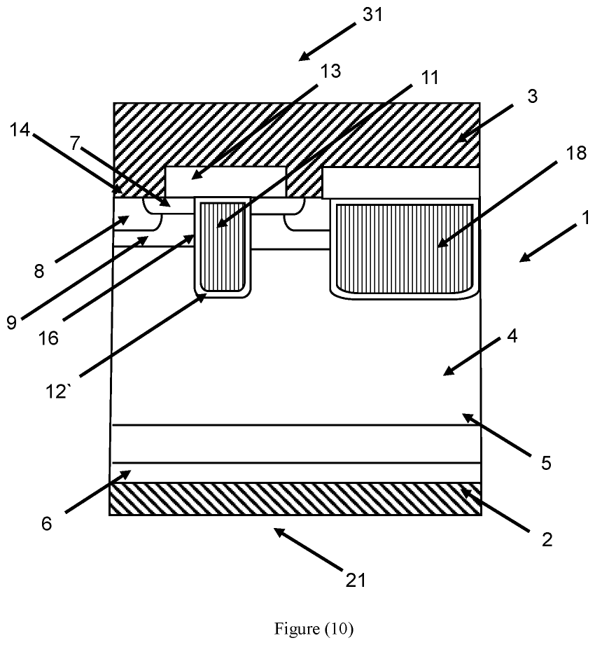

A first exemplary embodiment of a power semiconductor device (1) in form of a punch through insulated gate bipolar transistor (IGBT) with a four-layer structure (pnpn) is shown as top view representation in FIG. 9, and as schematic cross sections in FIG. 10 and FIG. 11. Herein references to a “top view” and “top plane view” will be understood to be references to the view shown in FIG. 9. The layers are arranged between an emitter electrode (3) on an emitter side (31) and a collector electrode (2) on a collector side (21), which is arranged opposite of the emitter side (31). The IGBT comprises an N-doped drift layer or substrate (4), which is arranged between the emitter side (31) and the collector side (21), the dopant concentration and thickness of this layer being selected to achieve the blocking voltage the semiconductor device is specified for. The thickness of the drift layer (4) may be for example in the range of several m to several hundred m. According to an embodiment, the substrate or drift layer (4) is made of a single crystalline semiconductor material such as Silicon, or a material having a band gap of 2.0 eV or higher such as gallium nitride (GaN) or silicon carbide (SiC).

An additional P-doped first base layer (9) is arranged between the drift layer (4) and the emitter electrode (3), and a second P-doped base layer (8) is arranged between the first base layer (9) and the emitter electrode (3), which second base layer (8) is in direct electrical contact to the emitter electrode (3), and has a higher doping concentration than the first base layer (9). An N-doped source region (7) is arranged at the emitter side (31) embedded into the first base layer (9), and contacts the emitter electrode (3), which source region has a higher doping concentration than the drift layer (4). The second base layer (8) extends perpendicularly deeper than the source region (7).

A plurality of main gate electrodes is arranged in trench structures (11), which are formed on the surface of the emitter side (31) and extend deeper into the drift layer (4) than the first base layer (9). The main gate electrodes (11) consist of a heavily doped polycrystalline layer or a metal-containing layer and are electrically insulated from the first base layer (9), the source region (7) and the drift layer (4) by a first insulating layer (12′). The first insulating layer (12′) may be a gate oxide layer. A vertical MOS channel (16) is formable between the emitter electrode (3), the source region (7), the first base layer (9) and the drift layer (4) when positive voltage is applied on the gate electrodes (11). The longitudinal direction of the main gate electrodes (11) is along a first horizontal direction (in a top plane view) which can be specific to a geometric axis in the starting material or can be randomly selected. The selection of the longitudinal direction may help to improve other characteristics of the power semiconductor.

According to a first embodiment, a plurality of second gate electrodes embedded in trench structures (18), is also arranged on the surface of the emitter side (31) and extend deeper into the drift layer (4) than the first base layer (9). The second gate electrodes are electrically insulated from the first base layer (9), and the drift layer (4) by a second insulating layer. Similarly to the first insulting layer (12′), the second insulating layer may be a gate oxide layer. The second insulating layer is characterized in that the second gate oxide can be identical with the first gate oxide (12′) or can be different in thickness and/or chemical composition. The second gate electrodes can be geometrically identical to the main gate electrodes, or can have different widths/depth/mesa. In a typical top plane view, the second gate electrodes (18) are arranged with their longitudinal axis at an angle between 45 degrees to 90 degrees compared to the longitudinal direction of the first gate electrodes (11) also defined above as first horizontal direction. Depending on the design, the second gate electrodes can be discontinued in the region of the main gate electrodes (11). A vertical channel can be formable on the surface of the second gate trenches between the emitter electrode (3), source region (7), the first base layer (9) and the drift layer (4), but it is not mandatory to the principle of this invention.

Further, an interlayer dielectric (13) electrically insulates the emitter electrode (3) from the gate electrodes (11) and (18) and may include by way of example one or more dielectric layers from silicon oxide, silicon nitride, silicon oxynitride, doped or undoped silicate glass, for example BSG (boron silicate glass), PSG (phosphorus silicate glass) or BPSG (boron phosphorus silicate glass).

In a first embodiment, a P-doped collector layer (6) is arranged on the collector side (2) in direct electrical contact to the collector electrode (2) and a buffer layer (5) is arranged between the collector layer (6) and the drift region (4). Layers (5) and (6) can also be omitted in other embodiments (e.g., unipolar MOSFET device, non-punch-through power semiconductor devices).

The trench regions can be better viewed in the top cell view shown in FIG. 9 for the first main embodiment of the inventive design. The inventive design consists of a basic trench MOS cell with main gate electrodes embedded in corresponding trench gate structures (11), formed along stripe-shaped designs, having a longitudinal axis extending along a first horizontal direction, and extending along the vertical direction from the emitter side (31) into the drift layer (4). The first horizontal direction, as well as at least one of the sidewalls or edges of the trench gate structures (11) may coincide with major crystal planes or may be tilted at angles between 0 degree and 45 degree with respect to major crystal planes. The trench gate structures (11) may be equally spaced and may form a regular pattern, wherein a pitch (center-to-center distance) is dependent on the longitudinal dimension or length of the second gate trenches and may be in a range from 1 μm to m, e.g., from 2 μm to 5 μm. According to another embodiment, the trench gate structures (11) can also have a pattern like arrangement on a top view of the surface of the emitter side (31) for example squares, hexagons, octagons or other regular polygons.

According to the first embodiment, second gate electrodes in second trench gate structures (18) are arranged in between the main gate electrodes trenches (11), at an angle between 45 degrees to 90 degrees with respect to the first horizontal direction (or the longitudinal direction of the main gate electrodes (11)). By means of example, only the 90 degrees case, e.g., trench structures (11) and (18) are orthogonal to each other, is shown in FIG. 10. The inventive design offers a clear path for charge extraction between the second gate electrodes (18) towards the emitter electrode (3) as shown in FIG. 11. Based on the numerous variations of processing, many different regions can be formed. In this first embodiment, only the vertical MOS channels (16) formed at the main gate electrodes (11) are active, while no channels are formed at the second gate electrodes (18). Nevertheless, it is also possible to form active vertical MOS channels at the second gate electrodes (18) by means known to those experienced in the field.

With respect to the top view shown in FIG. 9, one critical design aspect is the separation W_{MESA} between the edge of the main gate electrode trenches (11) and the edge of the second gate electrode trenches (18). An additional critical design aspect is the separation distance or mesa Wₜ between the long edges of adjacent second gate electrode trenches (18). Improved carrier storage/reduced hole drainage is expected as the dimensions Wₜ and W_{MESA} are reduced. The value of Wₜ may be in a range from about 5 μm to below 0.1 μm, more preferably from 1 μm to 0.1 μm—which is achievable with the proposed design because no additional structures have to be lithographically defined in between the trenches (18). Also, improved carrier storage/reduced hole drainage is expected with reducing the distance W_{MESA} by etching the adjacent trenches closer to each other. More specifically, W_{MESA} could extend approximately in a range from about 20 μm to about 0.5 μm, preferably from 5 μm to 0.5 μm, and more preferably from 2 μm to 0.5 μm.

The trenches embedding the main and second gate electrodes (11 and 18) extend in the direction of the drift layer (4) deeper than the first base layer (9). More specifically, the trench extends vertically to a depth approximately in a range from about 2 μm to about 10 μm. The trench width may range from about 4 μm to about 0.5 μm. The length of the second gate electrode trenches (18) can vary on the same structure with some of the trenches being shorter in length than the rest.

As a unique feature of the first embodiment, the second base layer (8) is structured to limit its extension in the direction of the long edge of the second gate trenches. Both the contact openings (14), and the second base layer (8) are encompassed within the distance WMESA. This reduces the hole drainage effect, and improves the safe operating area.

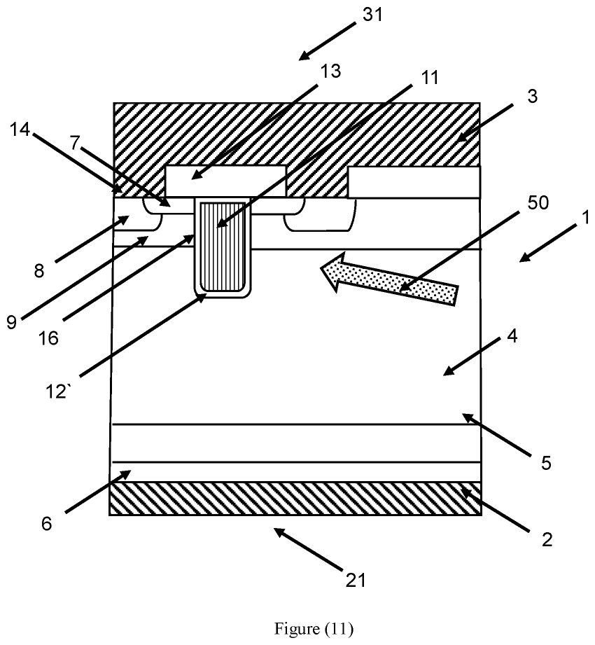

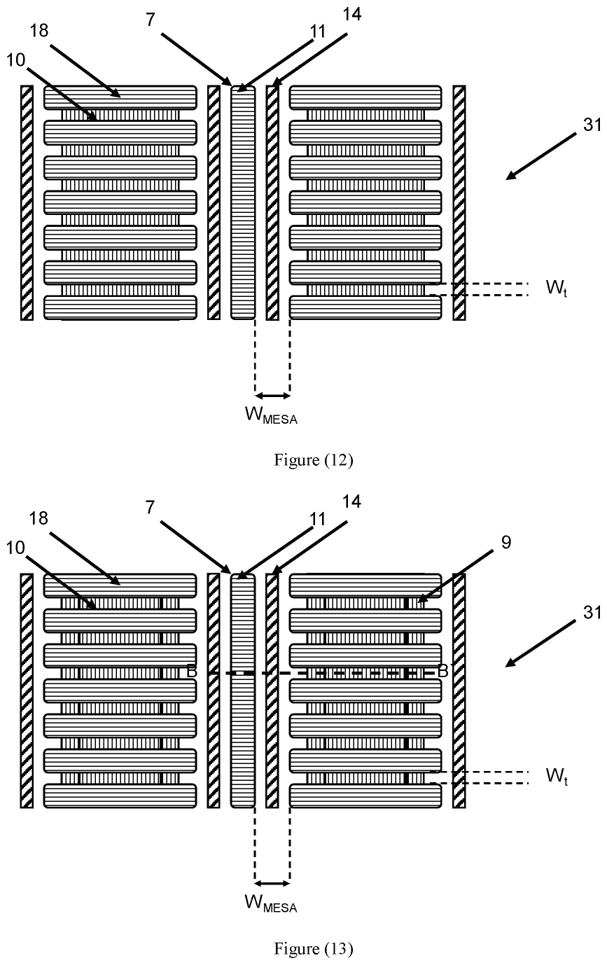

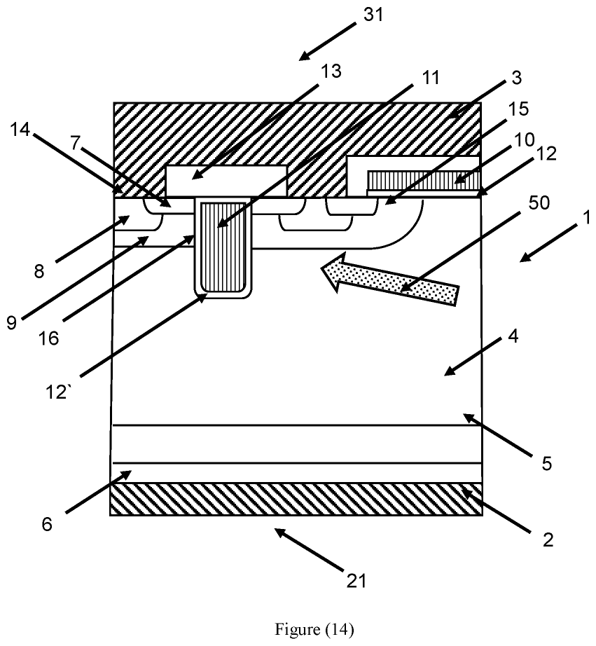

In a second embodiment represented as schematic top view in FIG. 12, the second trench gate electrodes (18) are in direct electrical contact with each other through additional planar gate electrodes (10). Layer (10) is electrically insulated from the first base layer (9) by an insulating layer (12) and does not extend laterally beyond the position of the short edges of the second gate trenches (18) in the direction of the contact openings (14). A horizontal MOS channel is not formable in the region between the long edges of the second gate trenches, because of the absence of a N-Source region near the planar region (10). FIG. 13 represents a third embodiment, wherein the first base layer (9) is further structured/interrupted in the region between the long edges of the second gate trenches. As shown in FIG. 14, a horizontal/planar MOS channel is formable in this case connecting the emitter electrode (3), the source region (7), the first base layer (9) and the drift layer (4) when a positive voltage is applied on the gate electrodes (10) and (18).

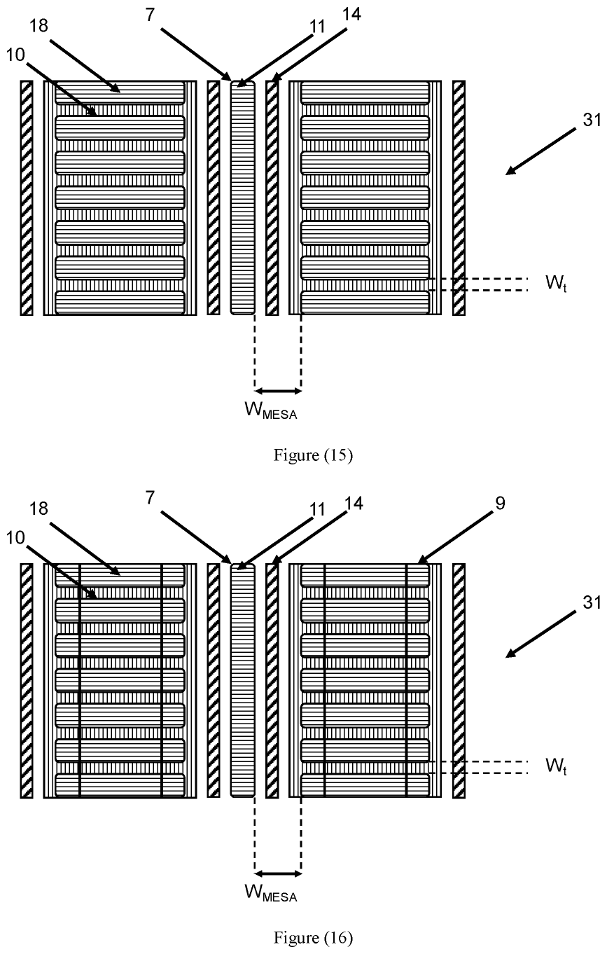

In a further fourth embodiment represented as schematic top view in FIG. 15, the planar gate electrodes (10) extend laterally beyond the position of the short edges of the second gate trenches (18), in the direction of contact openings (14). The first base layer (9) is uniformly formed in the region between the long edges of the second gate electrodes. Thus, no planar MOS channel is formable in this region. In the region between the short edges of the second gate trenches, a planar MOS channel can be formed in series with a vertical MOS channel.

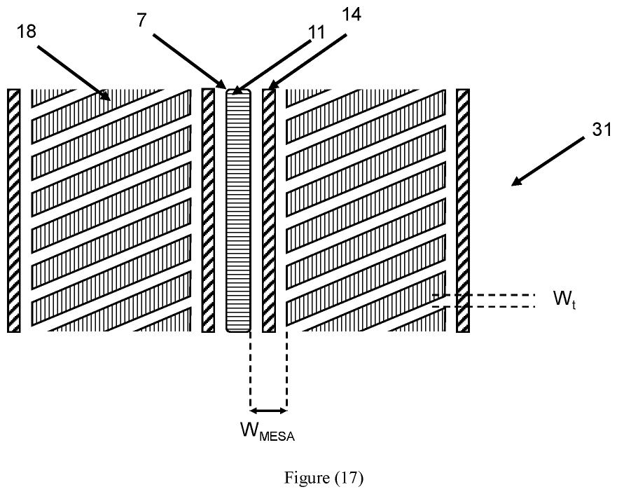

In a further fifth embodiment shown in FIG. 16 planar gate electrodes (10) extend beyond the position of the short edges of the second gate trenches towards the contact openings (14), and the first base layer (9) is structured in the region between the long edges of the second gate trenches. Consequently, a planar MOS channel is formable in this region, connecting the emitter electrode (3), the source region (7), the first base layer (9) and the drift layer (4) when a positive voltage is applied on the gate electrodes (10) and (18).

FIG. 17 shows a top view representation of a sixth exemplary embodiment with the first and second plurality of trench gate structures forming an angle different than 90 degrees.

The inventive design is also suitable for a reverse conducting semiconductor device by introducing N-type dopants at the collector side to form shorts in the P-type collector layer (6), and producing an internal anti-parallel diode structure.

A further embodiment includes the use of an enhancement layer of lightly doped N-type conductivity, implanted and diffused in the semiconductor device. The dopants are preferably Phosphorous ions. The dopants are preferably implanted with an energy of 20-100 keV and/or a dose of 5×10¹²/cm² to 5×10¹³/cm². The dopants are driven into a maximum depth between 2 μm and 8 μm, in particular between 2 and 6 μm and in particular between 2 and 4 μm. With this enhancement layer, the conduction losses of the semiconductor device are improved.

It is possible to apply the invention to a method for the manufacturing of semiconductor devices, in which the conductivity type of all layers is reversed, i.e. with a lightly p doped substrate etc.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

### REFERENCE LIST

1: inventive trench MOS cell-based power semiconductor device
2: collector metallization (electrode)
21: collector side
3: emitter metallization (electrode)
31: emitter side
4: drift layer, substrate
5: buffer layer
6: collector layer
7: n source layer
8: p second base layer
9: p first base layer
10: planar gate electrode, electrically conductive layer
11: first or main trench gate electrodes, electrically conductive layers
11′: first or main trench gate electrodes, electrically grounded or floating layers
12: insulating gate oxide for planar gate
12′: insulating gate oxide for trench gate
13: insulation layer for planar cell and trench cell
14: emitter contact opening
15: horizontal channel for planar gate
16: vertical channel for trench gate
17: p-type layer in dummy regions (trench MOS cells)
18: second trench gate electrodes, electrically conductive layers
50: charge extraction path during switching of the power semiconductor device
200: planar MOS cell power semiconductor device (prior art)
300: trench MOS cell power semiconductor device (prior art)
301: repetitive trench MOS cell power semiconductor device (prior art)
302: non-repetitive trench MOS cell power semiconductor device (prior art)

1-17. (canceled)

18. A power semiconductor device comprising:
a drift region of a first conductivity type having a thickness in a first dimension, comprising a first surface and a second surface;
a first electrode located at the first surface;
a second electrode located at the second surface;
a first base layer of a second conductivity type located between the first electrode and the drift region;
a source region of the first conductivity type located within the first base layer and electrically connected to the first electrode via a contact opening, wherein a doping concentration of the source region is greater than a doping concentration of the drift region;
a second base layer of the second conductivity type located within the first base layer and electrically connected to the first electrode via the contact opening, wherein a length of the second base layer in the first dimension is greater than a length of the source region in the first dimension, and wherein a doping concentration of the second base layer is greater than a doping concentration of the first base layer;
a plurality of first gate electrodes of a heavily doped polycrystalline layer or a metal layer and located within the first base layer and the drift region, wherein:
the plurality of first gate electrodes are electrically insulated from the first base layer, the source region, and the drift region by a first gate oxide layer;
the plurality of first gate electrodes are configured to form an MOS channel between the first electrode and the drift region; and
wherein the plurality of first gate electrodes extend longitudinally in a second dimension perpendicular to the first dimension;
a plurality of second gate electrodes of a heavily doped polycrystalline layer or a metal layer and located within the first base layer, wherein:
the plurality of second gate electrodes are electrically insulated from the first base layer, the second base layer, the source region, and the drift region by a second gate oxide layer;
the plurality of second gate electrodes extend longitudinally in a third dimension perpendicular to the first dimension, wherein the third dimension is oriented at an angle of greater than or equal to 45 degrees from the second dimension; and
the plurality of second gate electrodes are separated from the plurality of first gate electrodes in the third dimension;
an interlayer dielectric layer formed between the first electrode and the plurality of first gate electrodes and formed between the first electrode and the plurality of second gate electrodes; and
wherein the contact opening is bounded by the plurality of first gate electrodes and the plurality of second gate electrodes, and does not overlap with the plurality second gate electrodes; and
wherein each pair of adjacent first gate electrodes is interweaved with a plurality of second gate electrodes.

19. The power semiconductor device according to claim 18, wherein:
the plurality of first gate electrodes are each located in respective first trench structures, and
the plurality of second gate electrodes are each located in respective parallel second trench structures.

20. The power semiconductor device according to claim 19, wherein at least two of the second trench structures are separated in the third dimension by the first trench structures.

21. The power semiconductor device of claim 20, wherein at least one of:
at least two of the second trench structures have an equal length in the third dimension;
at least two adjacent second trench structures have different lengths in the third dimension;
at least two of the second trench structures have different separations to the plurality of first gate electrodes in the third dimension;
at least two of the second trench structures have an equal depth in the first dimension;
at least two adjacent second trench structures have different depths in the first dimension;
at least one of the second trench structures has a greater depth in the first dimension than the first trench structures;
at least two of the second trench structures have an equal width in the second dimension;
at least two adjacent second trench structures have different widths in the second dimension; and
at least one of the second trench structures has a greater width in the second dimension than a width of the first trench structures in the third dimension.

22. The power semiconductor device of claim 18, wherein at least one of:
the second gate oxide layer has a different thickness than the first gate oxide layer; and
the second gate oxide layer has a different chemical composition than the first gate oxide layer.

23. The power semiconductor device according to claim 18, wherein the plurality of first gate electrodes and the plurality of second gate electrodes are electrically connected, and wherein the source region is separated from the second gate oxide layer in the third dimension.

24. The power semiconductor device according to claim 18, wherein at least a portion of the source region abuts the second gate oxide layer.

25. The power semiconductor device according to claim 18, wherein at least one of the plurality of second gate electrodes is electrically connected to the first electrode.

26. The power semiconductor device according to claim 18, wherein at least one of the plurality of second gate electrodes is electrically floating.

27. The power semiconductor device according to claim 18, wherein at least one of the plurality of second gate electrodes is interconnected on the first surface via a third gate electrode located above the first surface.

28. The power semiconductor device according to claim 27, further comprising a third insulating layer located beneath the third electrode, wherein at least part of the third electrode is separated from the drift region by only the third insulating layer.

29. The power semiconductor device according to claim 18, comprising at least one of:
a collector layer of the second conductivity type formed between the drift region and the second electrode;
a buffer layer of the first conductivity type formed between the drift region and the second electrode, wherein a doping concentration of the buffer layer is greater than a doping concentration of the drift region; and
optionally wherein the buffer layer is formed between the collector layer and the second electrode.

30. The power semiconductor device according to claim 29, comprising:
a reverse conducting type device with a structured collector layer arranged at the second surface between the second electrode and the buffer layer, wherein the structured collector layer is formed by a pattern of opposite conductivity type regions.

31. The power semiconductor device according to claim 18, wherein an enhancement layer of the first conductivity type is formed between the drift region and the first base layer, wherein a doping concentration of the enhancement layer is greater than a doping concentration of the drift region.

32. The power semiconductor device according to claim 18, wherein a separation between adjacent second gate electrodes of the plurality of gate electrodes in the second dimension is between 5 μm to 0.1 μm.

33. The power semiconductor device according to claim 18, wherein the separation between the plurality of first gate electrodes and the plurality of second gate electrodes in the third dimension is between 20 μm to 0.5 μm.

34. The power semiconductor device according to claim 18, wherein the power semiconductor device has a stripe layout design or a cellular layout design.
